(19) United States
(12) Patent Application Publication
(10) Pub. No.: US 2024/0420927 A1
(43) Pub. Date: Dec. 19, 2024

(54) SYSTEM AND METHOD FOR CARBON PLUG FORMATION

(71) Applicant: Lam Research Corporation, Fremont, CA (US)

(72) Inventors: Daniela ANJOS RIGSBY, Tualatin, OR (US); Todd SCHROEDER, Sherwood, OR (US)

(21) Appl. No.: 18/701,384

(22) PCT Filed: Oct. 21, 2022
(86) PCT No.: PCT/US2022/078501

§ 371 Date: Apr. 15, 2024

Related U.S. Application Data
(60) Provisional application No. 63/263,493, filed on Nov. 3, 2021.

(51) Int. Cl. H01J 37/32; H01L 21/02; H01L 21/3105

(52) U.S. Cl. CPC H01J 37/32449; H01J 37/32165; H01J 37/32568; H01L 21/02115; H01L 21/31053; H01J 2237/332

(57) ABSTRACT

One example provides a fabrication tool comprising a chamber, a pedestal electrode and a showerhead electrode arranged in the chamber, one or more gas inlets into the chamber, a vacuum pump system, a radiofrequency (RF) power source configured to form an RF plasma between the pedestal electrode and the showerhead electrode, and a controller comprising a processor and memory. The memory comprises instructions executable by the processor to operate the flow control hardware to introduce a hydrogen-containing reducing agent and a hydrocarbon gas into the chamber, and to operate the RF power source to form a plasma between the pedestal electrode and the showerhead electrode to fully deposit a carbon plug in a recess of a workpiece positioned on a pedestal within the chamber in a single plasma deposition cycle with no intermediate carbon removal process.

### BACKGROUND

An integrated circuit may be fabricated on a substrate, such as a semiconductor wafer, via numerous cycles of region-selective masking, etching, and deposition.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to systems and methods for forming a carbon plug in a recess in an integrated circuit fabrication process. One example provides a fabrication tool comprising a chamber, a pedestal electrode and a showerhead electrode arranged in the chamber. The fabrication tool further comprises one or more gas inlets into the chamber and associated flow control hardware. The fabrication tool further comprises a vacuum pump system and a radiofrequency (RF) power source configured to form an RF plasma between the pedestal electrode and the showerhead electrode. The fabrication tool further comprises a controller comprising a processor and memory. The memory comprises instructions executable by the processor to operate the flow control hardware to introduce a hydrogen-containing reducing agent into the chamber, and to introduce a hydrocarbon gas into the chamber. The instructions are further executable to operate the RF power source to form a plasma between the pedestal electrode and the showerhead electrode to fully deposit a carbon plug in a recess of a workpiece positioned on a pedestal of the chamber in a single plasma deposition cycle with no intermediate carbon removal process.

In some such examples, the instructions are executable to operate the RF power source to provide RF power having one or more frequencies within a range of five megahertz and higher.

In some such examples, the instructions are executable to operate the RF power source to provide RF power that excludes frequencies below five megahertz.

In some such examples, the hydrocarbon gas comprises an alkyne.

In some such examples, the alkyne comprises acetylene.

In some such examples, the instructions are executable to operate the flow control hardware to introduce hydrogen and the hydrocarbon gas into the chamber at a molar ratio of 20-35% hydrogen-containing reducing agent.

In some such examples, the instructions are further executable to further introduce one or more of argon or nitrogen into the chamber as a diluent gas.

In some such examples, the instructions are further executable to operate the flow control hardware to deposit the carbon at a processing gas pressure between 5 and 13 Torr.

In some such examples, the fabrication tool further comprises one or more heaters, and the instructions are further executable to operate the one or more heaters to maintain the pedestal electrode at a temperature within a range of 275-660° C. during plug formation.

In some such examples, the instructions are further executable to extinguish the plasma after the workpiece is exposed to the plasma for a duration within a range of 700 to 1800 seconds.

Another example provides an integrated circuit fabrication process. The fabrication process comprises forming a carbon plug in a recess of a workpiece in a single plasma deposition cycle by exposing the workpiece to a carbon-depositing plasma in a plasma processing chamber. The carbon-depositing plasma is formed from a mixture of gasses comprising a hydrogen-containing reducing agent and a hydrocarbon gas.

In some such examples, the carbon-depositing plasma comprises a radiofrequency (RF) plasma comprising one or more frequencies within a range of five megahertz and higher, to the substantial exclusion of frequencies below five megahertz.

In some such examples, the hydrocarbon gas comprises an alkyne.

In some such examples, the hydrogen-containing reducing agent and the hydrocarbon gas are introduced into the chamber at a molar ratio of 20-35% hydrogen.

In some such examples, the mixture of gases further comprises one or more of argon or nitrogen.

In some such examples, the carbon plug is formed at a processing gas pressure between 5 and 13 Torr.

In some such examples, the method further comprises planarizing the workpiece after the single plasma deposition cycle, thereby removing carbon deposited outside of the recess.

In some such examples, the recess defines a channel of a memory stack structure.

Another example provides a method of fabricating a memory stack structure. The method comprises supporting a workpiece on a pedestal of a deposition chamber. The deposition chamber comprises a pedestal electrode separated from a showerhead electrode by an interelectrode space. The workpiece comprises a recess in a first memory deck. The method further comprises flowing a mixture of gases through the chamber at reduced pressure. The mixture of gases comprises a hydrogen-containing reducing agent, and also comprises a hydrocarbon. The method further comprises driving RF current through a discharge gap between the pedestal electrode and the showerhead electrode to form a carbon-depositing plasma and deposit a carbon plug in the recess in a single deposition cycle. The method further comprises planarizing the workpiece after forming the carbon plug, and depositing layers of a second memory deck over the first memory deck and the carbon plug.

In some such examples, the hydrocarbon comprises an alkyne.

In some such examples, the carbon plug is formed at a processing gas pressure between 5 and 13 Torr.

In some such examples, the pedestal electrode is maintained at a temperature within a range of 275-660° C. during plug formation.

### BRIEF DESCRIPTION OF THE DRAWINGS

FIGS. 1A-1F schematically show intermediate structures in an example memory stack fabrication process that includes the formation of a carbon plug as an etch stop.

FIGS. 2A-2C schematically show the formation of a relatively thinner carbon plug by using a single-cycle deposition process.

FIGS. 3A-3E schematically show the formation of a relatively thicker carbon plug via an example multi-cycle deposition/etch process.

FIGS. 4A-4C schematically show the formation of a relatively thicker carbon plug via an example single-cycle deposition process that utilizes a mixture of gases comprising a hydrogen-containing reducing agent.

FIG. 5 shows aspects of an example plasma-enhanced chemical vapor deposition tool.

FIG. 6 shows a flow diagram depicting an example integrated circuit fabrication process.

FIG. 7 shows a block diagram depicting an example computing system.

### DETAILED DESCRIPTION

A density of integrated circuit components on a semiconductor die is limited by factors such as feature size constraints imposed by current photolithography techniques. However, by transitioning from two-dimensional (2D) to three-dimensional (3D) integrated circuit fabrication, much larger device densities are achievable via stacking of components within an integrated circuit.

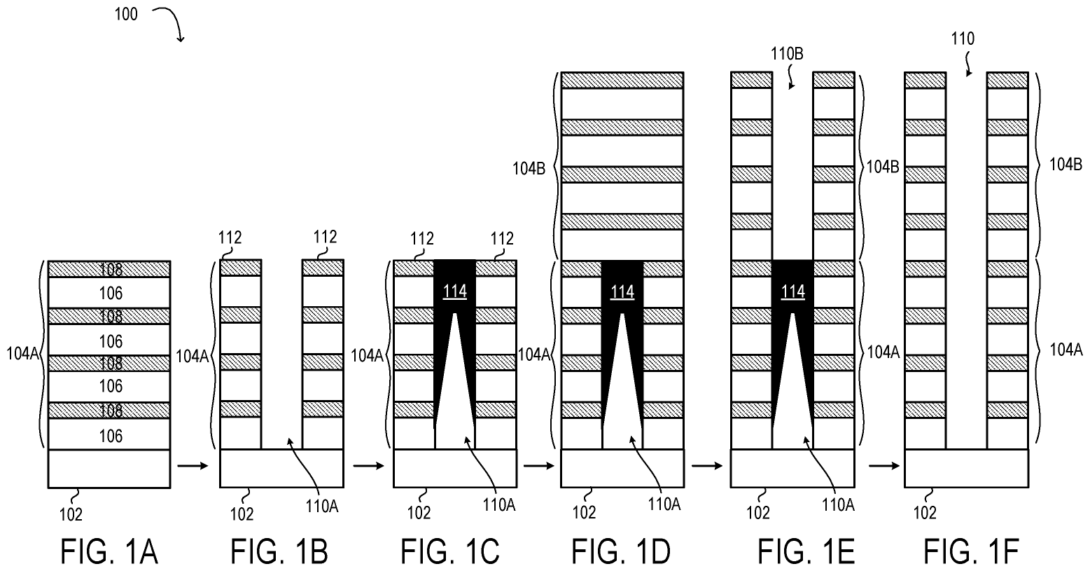

FIGS. 1A-1F schematically show intermediate structures formed during an example process 100 used to form a 3D memory stack structure. FIG. 1A shows a substrate 102 on which a deck 104A comprising an alternating stack of layers of a first material 106 and a second material 108 is formed as an intermediate structure in a 3D NOT AND (NAND) memory structure fabrication process. The term NAND represents a NOT-AND logic gate architecture of the memory. Substrate 102 represents any suitable structures onto which an alternating stack of layers can be formed in a 3D NAND fabrication process. In some examples, first material 106 comprises an oxide, such as silicon oxide, and second material 108 comprises a nitride, such as silicon nitride. In other examples, first material 106 may comprise silicon oxide and second material 108 may comprise polysilicon. In further examples, deck 104A may include an alternating stack of any other suitable first material 106 and second material 108. Parts numbers for first material 106 and second material 108 are omitted for figures subsequent to FIG. 1A, and are instead represented collectively by deck 104A.

FIG. 1B shows deck 104A after a recess 110A has been etched through deck 104A to substrate 102. Recess 110A serves as a channel hole in which channel structures for 3D NAND memory are formed in later fabrication processes. Recess 110A is surrounded by a field region 112 of second material 108, but may be surrounded by a field region of first material 106 in other examples. Recess 110A may be formed via any suitable etching process, such as a plasma etch combined with appropriate masking. As illustrated, recess 110A has a relatively high aspect ratio, such as a depth:width ratio within a range of 60:1-100:1 in some examples. In some examples, recess 110A may have a width of 90 nanometers (nm) and a depth of 6000-11000 nm.

The use of a greater number of alternating layers of first material 106 and second material 108 allows a greater number of NAND memory cells to be fabricated on substrate 102. However, practical limits exist regarding the depth of a recess that may be formed by directional etching. One way to address such a limit on etching depth is to fabricate 3D NAND memory in multiple stages. In such a process, a second deck of alternating materials is formed over deck 104A after etching recess 110A. However, fabricating 3D NAND memory by the deposition and etching of multiple decks poses various challenges. For example, a directional etch used to form a recess in a second deck of alternating materials can potentially damage the interior of recess 110A. One approach to protecting the interior of recess 110A is to protect recess 110A with a suitable etch stop layer after the recess 110A is formed but before deposition of a next deck of alternating materials has begun. A carbon plug may be well-suited for use as an etch stop layer to protect recess 110A. Carbon may resist the directional etch chemistry used to form recess 110A. Further, carbon may be conveniently removed from high aspect ratio recesses by an ashing process. Such a carbon plug may be formed by depositing carbon within recess 110A and in field region 112 around recess 110A. The deposited carbon then may be mechanically planarized (for example, using chemical mechanical polishing (CMP)) to remove carbon from field region 112, leaving a carbon plug. FIG. 1C illustrates an intermediate structure formed by depositing carbon within recess 110A followed by planarization, resulting in carbon plug 114 that is substantially co-planar with adjoining field region 112. As shown in FIG. 1D, planarizing the top surface of deck 104A provides a suitable surface on which to deposit alternating first material and second material layers of a second deck 104B. In some examples, carbon plug 114 comprises amorphous carbon. The amorphous carbon may have nanoscale crystallites comprising both sp² and sp³ carbon. In other examples, carbon plug 114 can have any other suitable composition.

Referring next to FIG. 1E, after second deck 104B is formed by the deposition of alternating material layers (as described above with regard to FIG. 1A), a recess 110B is etched in deck 104B in spatial registration with recess 110A, using appropriate patterning techniques. In one example, the patterning techniques employed for etching recess 110B may be similar to the techniques described above for etching recess 110A. In another example, the patterning techniques employed for etching recess 110B may be different from the techniques described above for etching recess 110A. Carbon plug 114 serves as an etch stop in this process. Referring next to FIG. 1F, after the etching of recess 110B, carbon plug 114 is removed by ashing to join recess 110A and 110B into a joined recess 110. The processes of FIGS. 1A-F can be repeated to form a recess extending through any suitable number of decks. Alternatively, the processes of FIGS. 1A-E can be repeated to form a plurality of decks, and then the resulting plurality of carbon plugs can be removed in a single ashing step. A 3D NAND channel then may be formed within joined recess 110 using subsequent processing steps not illustrated herein.

The amorphous carbon that forms carbon plug 114 may be deposited in recess 110A via plasma-enhanced chemical-vapor deposition (PECVD). A carbon-containing precursor for the PECVD process may be a carbon-containing gas, such as a low molecular-weight hydrocarbon. Examples of such gases comprise alkanes having a general formula CₙH₂ₙ₊₂ where n=0 to 10 (such as, methane, ethane, etc.), alkenes having a general formula CₙH₂ₙ where n=0 to 10 (such as, ethylene, propylene, etc.), alkynes having a general formula CₙH₂ₙ₋₂ where n=0 to 10 (such as, acetylene, propyne, etc.) and other hydrocarbons (such as, cyclic hydrocarbons and nitrogen-containing compounds) that are gas-phase under processing conditions.

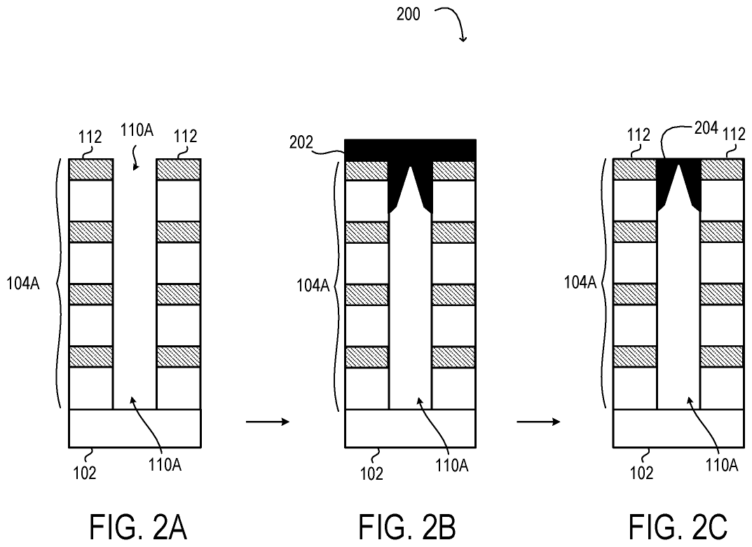

However, the PECVD deposition of amorphous carbon to form a carbon plug may pose challenges. For example, a sticking coefficient (a ratio of the number of precursor molecules that adsorb to the surface to the total number of precursor molecules that impinge the surface) of the carbon-containing precursor molecules may cause carbon to form a thin plug. FIGS. 2A-C schematically show selected aspects of a PECVD process 200 to illustrate this issue. FIG. 2A represents recess 110A before depositing carbon. FIG. 2B represents recess 110A after depositing carbon 202. As shown, carbon may tend to deposit preferentially on the field region 112 of deck 104A and in a relatively shallower part of the recess due to the sticking coefficient of the carbon-containing precursor. With continued deposition, further accumulation of carbon in the shallow part of the recess causes the opening of recess 110A to close off. This forms a carbon layer 202 having a relatively shallower depth below the opening of recess 110A. Planarization thereby yields a relatively thinner carbon plug 204. Such a relatively thinner carbon plug 204 may be fragile and may offer unreliable etch stopping properties.

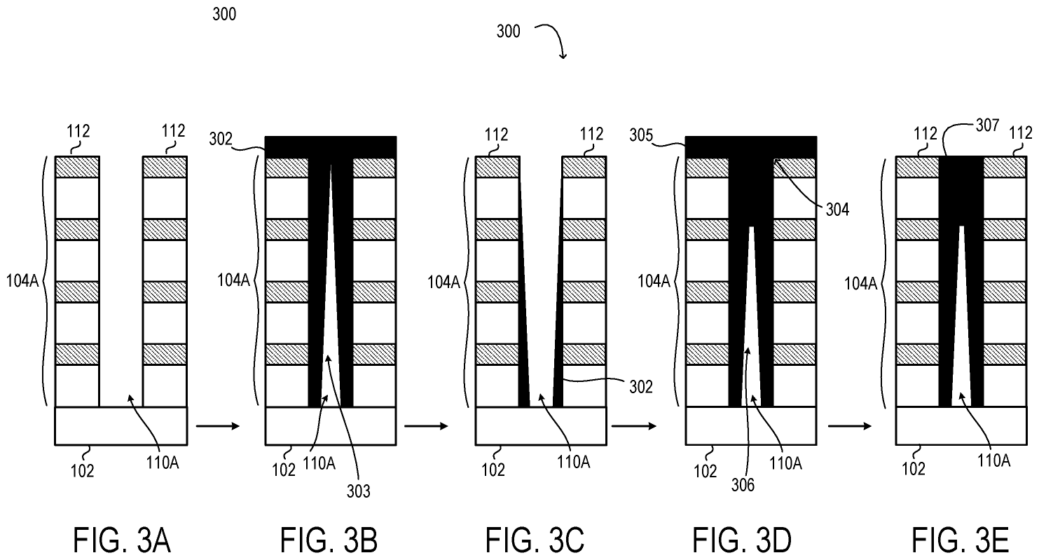

One possible method to form a relatively thicker carbon plug than that formed by the process of FIG. 2 is to use multiple cycles of deposition and etching in the carbon plug formation process, combined with the use of an etchant gas during PECVD that mitigates the preferential deposition of carbon close to the opening of a recess. While such a method may form a more robust plug, a disadvantage is the performance of multiple carbon deposition/removal cycles. Such a multi-cycle approach is illustrated at 300 in FIGS. 3A-E. FIG. 3A shows recess 110A before depositing carbon. Next, carbon is deposited into recess 110A via PECVD. For instance, carbon layer 302 is deposited using multiple, sequential cycles of deposition and etching processes. By way of example, field region 112 is exposed to carbon-containing precursor (e.g., a hydrocarbon, such as acetylene) in presence of a non-reactive gas (e.g., Ar and/or N₂) to form carbon layer 302. Carbon layer 302 is then exposed to a carbon-containing etchant gas, such as carbon dioxide (CO₂). The etchant gas compensates for the relatively high sticking coefficient of the carbon-containing precursor.

As depicted in FIG. 3B, a carbon layer 302 is deposited relatively deeply in recess 110A, and as shown, in one example, extends into substrate 102. In one example, as shown, carbon layer 302 is deposited along the sidewalls of field regions 112 (FIG. 3A), with carbon layer 302 also extending laterally over field region 112, causing carbon layer 302 that is deposited within recess 110A to be pinched off at an upper surface of recess 110A. This pinch-off results in carbon layer 302 to form an inverted V-shape with a void 303 within recess 110A.

Next, a plasma etch removes carbon deposited on the field region 112 of deck 104A while also partially etching a portion of carbon layer 302 deposited within recess 110A. This etching process may preferentially etch carbon layer 302 within recess 110A closer to an opening 304 of recess 110A compared to farther from opening 304 to produce the structure shown in FIG. 3C. The next cycle of deposition adds additional carbon 305 within recess 110A and over field region 112 of deck 104A until the opening is again closed, resulting in the structure illustrated in FIG. 3D. In the structure of FIG. 3D, void 306 is spaced farther from opening 304 than void 303. Additional etching and deposition cycles may be performed until a carbon layer of sufficient thickness is obtained within recess 110A. This structure is then planarized to remove field regions of additional carbon 305, leaving carbon plug 307 disposed within recess 110A, illustrated in FIG. 3E. In some examples, carbon plug 307 fills recess 110A to a depth of at least two times a width of recess 110A. Such a carbon plug 307 may provide sufficient solidity to withstand the stress of planarization and act as a robust etch stop in a subsequent channel recess etch process. In other examples, carbon plug 307 may fill recess 110A to any other suitable depth.

As mentioned above, a disadvantage of the carbon plug formation process illustrated in FIGS. 3A-E is the need for multiple carbon deposition/removal processes to form a suitably thick carbon plug. In some examples, the carbon plug formation process may require a potentially large number (for example, >3-5) of cycles of deposition and removal. Such cycling may add manufacturing time and cost to the device being fabricated.

Accordingly, examples are disclosed that relate to forming carbon plugs of suitable thickness to act as an etch stop layer using a single deposition cycle, without intermediate carbon removal steps followed by other carbon deposition cycles that are typically performed for forming a conventional carbon plug. The carbon plugs thus formed may be suitable for use as an etch stop layer in a 3D NAND channel etch process or other integrated circuit manufacturing process. Briefly, at least one carbon-containing precursor and one or more hydrogen-containing reducing agents, such as molecular hydrogen (H₂)_and/or ammonia (NH₃), are used in a mixture of gases for carbon deposition. Examples of carbon-containing precursors include alkanes having a general formula CₙH₂ₙ₊₂ where n=0 to 10 (such as, methane, ethane, etc.), alkenes having a general formula CₙH₂ₙ where n=0 to 10 (such as, ethylene, propylene, etc.), alkynes having a general formula CₙH₂ₙ₋₂ where n=0 to 10 (such as, acetylene, propyne, etc.), and other hydrocarbons (such as, cyclic hydrocarbons and nitrogen-containing compounds), that are in gaseous phase under processing conditions.

Without wishing to be bound by theory, the inclusion of one or more of hydrogen-containing reducing agents (for example, hydrogen and/or ammonia) in the single-cycle carbon plug deposition process mitigates the high sticking coefficient of the carbon-containing precursor gas by acting as an etchant during deposition. This allows carbon to grow more evenly at different depths within the recess.

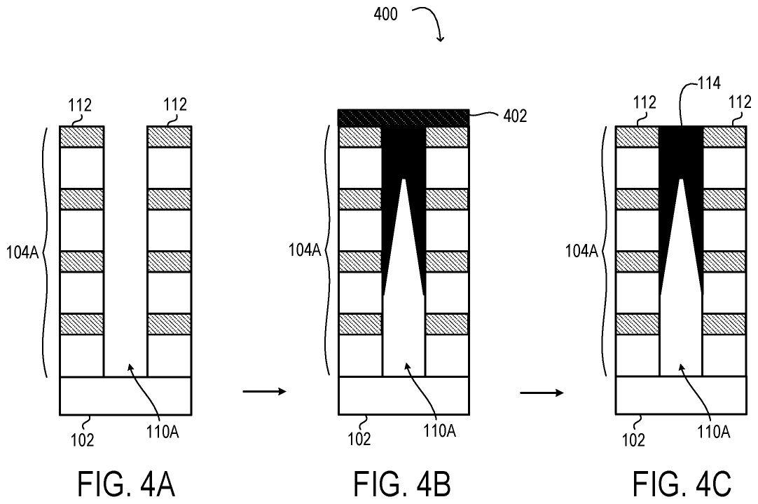

FIGS. 4A-C illustrate an example process 400 for forming a carbon plug in a single deposition cycle followed by planarization in accordance with one or more embodiments of the present disclosure. FIG. 4A shows deck 104A and recess 110A prior to carbon deposition. Referring next to FIG. 4B, a single carbon deposition cycle using a hydrogen-containing reducing agent and a carbon-containing precursor (e.g., hydrocarbon gas) forms a carbon layer 402 of sufficient thickness to provide a robust carbon plug within recess 110A. In some examples, the hydrogen-containing reducing agent and the carbon-containing precursor are included in a molar ratio of 20-35% hydrogen-containing reducing agent. As shown in FIG. 4B, the single carbon deposition cycle deposits carbon layer 402 along the sidewalls of field regions 112 and extending laterally over field region 112. Planarization of any unnecessary carbon layer 402 results in the formation of carbon plug 114 of FIG. 4C and the removal of carbon from field region 112. The resulting structure, illustrated in FIG. 4C, provides a suitable structure for depositing alternating layers for a next memory deck. Thus, multiple cycles of carbon deposition and etching are avoided. In some examples, a ratio of carbon-containing precursor and hydrogen-containing reducing agent may be varied to control a depth of carbon layer deposition in a recess.

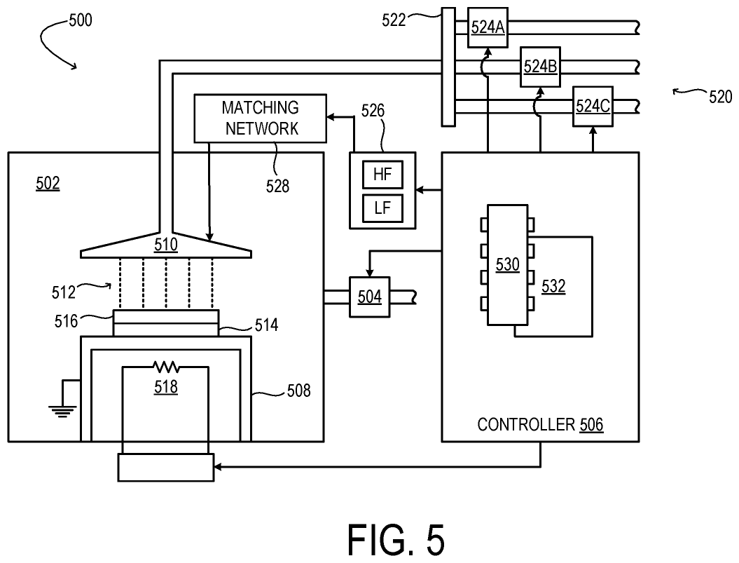

Prior to discussing a single-cycle carbon plug formation process in detail, FIG. 5 shows an example fabrication tool 500 that may be used to perform form a carbon plug deposition process according to the present disclosure. It will be understood that fabrication tool 500 is illustrative and not limiting, as other suitable tools may be used to practice the example methods disclosed herein. Any suitable fabrication tool may be used.

Fabrication tool 500 takes the form of a PECVD tool comprising a deposition chamber 502. Deposition chamber 502 is configured to be maintained at a reduced pressure during deposition processes via a vacuum pump system 504 comprising one or more pumps. Vacuum pump system 504 is in electrical communication with a controller 506 configured to output control signals to vacuum pump system 504 and other components described below.

Pedestal electrode 508 and showerhead electrode 510 are arranged within deposition chamber 502. Pedestal electrode 508 and showerhead electrode 510 are separated by an interelectrode space that defines a discharge gap 512. A pedestal 514 is arranged on or integrated with pedestal electrode 508, and a workpiece 516 (in this example, a wafer) is shown as arranged on pedestal 514. In the illustrated example, a heater 518 is positioned below pedestal electrode 508. The heater 518 is controlled via control signals from controller 506, so as to maintain the pedestal electrode 508 at a desired setpoint temperature.

Fabrication tool 500 further comprises flow control hardware 520 configured to flow a mixture of gases though deposition chamber 502 at reduced pressure. Flow control hardware 520 comprises a manifold 522 and a series of mass-flow and/or volume-flow controllers 524A, 524B, 524C, which provide a metered flow of each of a plurality of gases, as controlled by control signals from controller 506. As described in greater detail below, the gases metered by the flow controllers 524A, 524B, 524C include a hydrogen-containing reducing agent and at least one hydrocarbon. In some examples, one or more other gases (e.g. nitrogen (N₂), helium (He), and/or argon (Ar)) also may be metered, e.g. as one or more diluent gases, and/or purging gases). While three flow controllers 524A, 524B, 524C are shown in the example of FIG. 5, any other suitable number of flow controllers may be used in other examples.

Fabrication tool 500 further comprises a power supply 526 configured to drive a current through the discharge gap between showerhead electrode 510 and pedestal electrode 508. To this end, power supply 526 receives control signals from the controller 506 to control various aspects of the current driven. Power supply 526 includes one or more radiofrequency (RF) power supplies configured to drive RF current through the discharge gap. Different RF power supplies may be provided for different RF bands. Such bands may include, for example, a high-frequency (HF) band comprising frequencies of 5 megahertz (MHz) or greater, and a low-frequency (LF) band comprising frequencies less than 5 MHz. The current driven through the discharge gap 512 may support a carbon-depositing plasma comprising ions made by ionization of the mixture of gases in the deposition chamber 502. Fabrication tool 500 further comprises a matching network 528 disposed between power supply 526 and showerhead electrode 510 for impedance matching of the RF power supply.

As mentioned above, controller 506 of fabrication tool 500 is coupled operatively to vacuum pump system 504, heater 518, flow controllers 524, power supply 526, as well as to other controllable components of the fabrication tool 500. Controller 506 comprises at least one processor 530 and memory 532. Memory 532 holds instructions executable by the at least one processor 530 to direct controller 506 to enact any of the control functions associated with the fabrication processes disclosed herein, among other functions. In some examples, controller 506 may be local to other components of fabrication tool 500. In other examples, controller 506 may be located remotely to other components of fabrication tool 500. In yet other examples, controller 506 may be distributed between local and remote locations with reference to fabrication tool 500. Example hardware components suitable for use in controller 506 are described in more detail below with reference to FIG. 8.

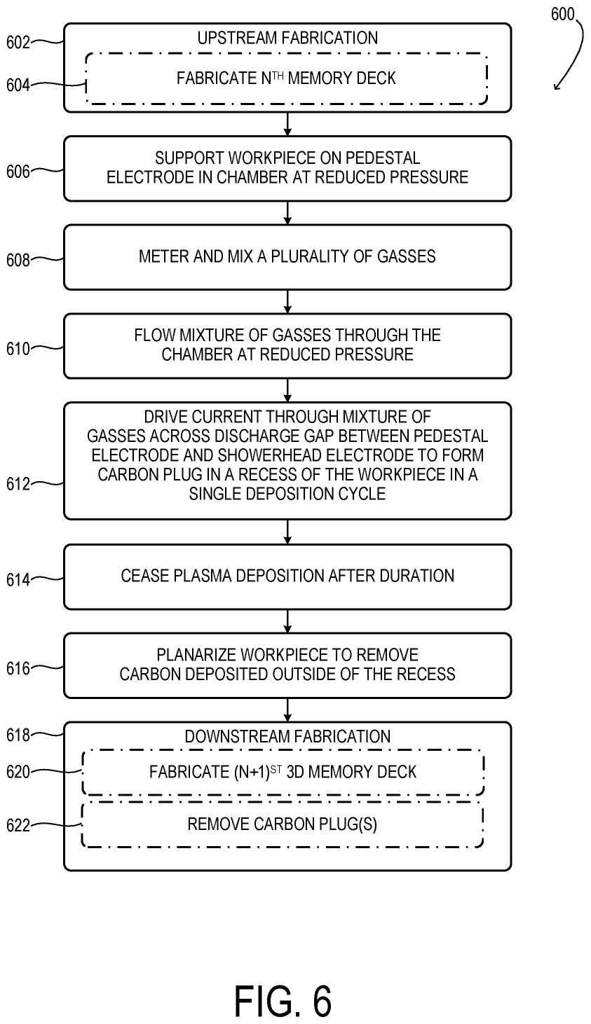

FIG. 6 shows a flow diagram depicting an example method 600 for forming a carbon plug during fabrication of an integrated circuit, such as a memory stack structure (e.g. a 3D NAND memory stack or other suitable memory stack, such as a 3D NOR (NOT-OR) memory stack). Method 600 is described with reference to components of the fabrication tool of FIG. 5, but it will be understood that method 600 may be performed using any suitable tools and/or technologies. Method 600 may be performed by deposition tool 500 via execution by controller 506 of instructions stored in memory 532.

As indicated at 602, various upstream fabrication processes are performed prior to the forming of a carbon plug within a recess on a workpiece. In some examples, and as indicated at 604, the upstream fabrication processes are performed to fabricate an Nth 3D memory deck, wherein Nis an integer greater than zero. As such, the term “Nth” may represent a first, a second, a third, etc. memory deck. The Nth 3D memory deck comprises a plurality of alternating material layers (e.g. oxide/nitride or oxide/polysilicon), and an etched recess to accommodate fabrication of a memory channel structure. In other examples, the upstream fabrication processes may form a recess corresponding to any other suitable intermediate structure in a device fabrication process.

Method 600 further comprises at 606, supporting the workpiece on a pedestal electrode arranged in a chamber at reduced pressure. As noted above, the pedestal electrode is separated from a showerhead electrode by an interelectrode space defining a discharge gap. At 608, method 600 comprises metering and mixing a plurality of gases to form a mixture of gases for plasma processing. In some examples the mixture of gases comprises a hydrogen-containing reducing agent and at least one hydrocarbon. The hydrogen-containing reducing agent and the at least one hydrocarbon may be metered into the chamber at any suitable ratio. In some examples, the hydrogen-containing reducing and the at least one hydrocarbon are introduced into the chamber at a molar ratio of 20-35% hydrogen-containing reducing agent. In a more specific example, the molar ratio of the hydrogen-containing reducing agent and the at least one hydrocarbon is substantially 1:4, wherein the term “substantially” indicates a tolerance range within which the flow controllers and other process hardware can control the molar ratio. In some examples, the gases may be mixed in a manifold prior to introduction into the chamber, while in other examples the gases may mix after separate introduction into the chamber. Further, in some examples, the hydrogen-containing reducing agent may be one or more of H₂ or NH₃.

Any suitable hydrocarbon compound or compounds may be used as the at least one hydrocarbon. In some examples, the at least one hydrocarbon comprises acetylene. In other examples, the at least one hydrocarbon comprises methane and/or propylene. In yet other examples, the at least one hydrocarbon comprises any other suitable material. Examples of suitable materials may include alkanes having a general formula CₙH₂ₙ₊₂ where n=0 to 10 (such as, methane, ethane, etc.), alkenes having a general formula CₙH₂ₙ where n=0 to 10 (such as, ethylene, propylene, etc.), alkynes having a general formula CₙH₂ₙ₋₂ where n=0 to 10 (such as, acetylene, propyne, etc.) and other hydrocarbons (such as, cyclic hydrocarbons and nitrogen-containing compounds) that are gas-phase under processing conditions.

In some examples, the mixture of gases may comprise nitrogen, e.g. as a diluent gas. In a more particular example, the molar ratio of nitrogen to the at least one hydrocarbon may be within 20% of a 4:5 molar ratio.

In some examples, the mixture of gases may also comprise argon, e.g. as diluent gas. In some examples, a molar ratio of the argon to the at least one hydrocarbon may be within 20% of a 12:5 molar ratio. In some examples, the mixture of gases substantially excludes carbon dioxide. The term “substantially excludes” represents that no carbon dioxide is intentionally introduced into the mixture of gases, and any carbon dioxide in the mixture is present as an impurity.

As indicated at 610, the mixture of gases is flowed through the chamber at reduced pressure. In some examples, the absolute pressure of the mixture of gases is between 5 and 13 Torr. In some examples, while the mixture of gases is flowed through the chamber at reduced pressure, the pedestal electrode is maintained at a setpoint pedestal electrode temperature. The setpoint pedestal electrode temperature may be within a range of 275-660° C. in some examples. Further, the setpoint may be controlled in a closed-loop manner in some examples. Likewise the showerhead electrode may be maintained at a setpoint showerhead electrode temperature. The setpoint showerhead electrode temperature may be within 240-360° C. in some examples. The setpoint temperature also may be controlled in a closed-loop manner.

Continuing, at 612, method 600 comprises driving current through the mixture of gases, across the discharge gap between the pedestal electrode and the showerhead electrode. Such current maintains a carbon-depositing plasma comprising ions from the ionization of gases within the mixture of gases. In some examples, the current driven through the discharge gap comprises RF current to form an RF plasma. In some such examples, the RF current comprises one or more frequencies of five megahertz or higher, to the substantial exclusion of frequencies below five megahertz. As described above, the use of a processing gas mixture that comprises a hydrogen-containing reducing agent in addition to a hydrocarbon may mitigate a high sticking coefficient of the hydrocarbon. This may help to form, via a single deposition cycle, a carbon plug having a suitable thickness to act as an etch stop layer in a subsequent etching process. An example of a subsequent etching process is a 3D memory structure channel etching process, as shown in FIGS. 1D-E. In some examples, the carbon plug fills the recess to a depth of at least two times the width of the recess. In other examples, the carbon plug fills the recess to any other suitable depth.

At 614, method 600 comprises ceasing plasma deposition after the workpiece has been exposed to the plasma for a duration. In some examples, such as those that use the above-described processing conditions, the duration may fall within a range of 900 to 1300 seconds. In other examples, the duration may fall within any other suitable range of times. At 616, the workpiece is planarized after deposition of the carbon, thereby removing the carbon deposited outside of the recess. The planarization may remove the carbon down to the opening of the recess. Any suitable process may be used to remove carbon deposited outside of the recess. In some examples, a CMP process may be used.

Upon planarization of the deposited carbon after the single cycle deposition of the carbon, the carbon plug fabrication process is complete. After forming the carbon plug, various downstream fabrication processes may be performed that use the carbon plug, as indicated at 618. As one example, downstream fabrication processes may include, at 620, fabrication of memory deck (N+1). Such a process may comprise, for example, depositing alternating material layers of (N+1) deck over the Nth deck. Such a process also may comprise forming a recess in memory deck (N+1) by a directional etch process. The recess formed in memory deck (N+1) extends to the carbon plug formed in the recess of the. After forming the recess in memory deck (N+1), the carbon plug(s) formed to protect earlier-formed memory decks are removed at 622. The carbon plug removal may be conveniently performed by an ashing process, as one example.

In an experiment, a first carbon plug structure and a second carbon plug structure were fabricated using acetylene. The first carbon plug structure was fabricated in conditions including a flow of hydrogen gas. The second carbon plug structure was fabricated in similar conditions but with no flow of hydrogen gas. The deposition conditions included nitrogen and argon as well as acetylene and hydrogen, within compositional ranges, pressures, and temperature ranges described above.

The first carbon plug structure extended to a depth of about 3.2 times the width of the recess portion. In contrast, the second carbon plug structure extended to a depth of only a fraction of the width of the recess portion. This experiment demonstrated the advantageous effect of including a hydrogen-containing reducing agent (in this example, hydrogen) together with the acetylene in the mixture of gases admitted to the chamber under the tested processing conditions.

In some embodiments, the methods and processes described herein may be tied to a computing system of one or more computing devices. In particular, such methods and processes may be implemented as a computer-application program or service, an application-programming interface (API), a library, and/or other computer-program product.

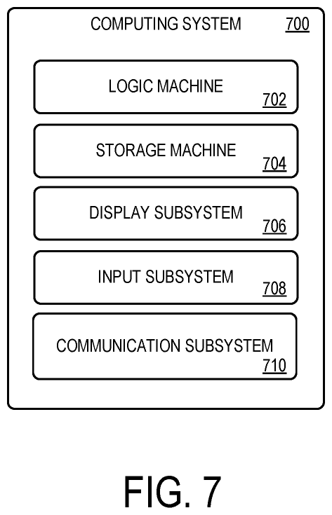

FIG. 7 schematically shows a non-limiting embodiment of a computing system 700 that can enact one or more of the methods and processes described above. Computing system 700 is shown in simplified form. Computing system 700 may take the form of one or more personal computers, server computers, and computers integrated with processing equipment, as examples. Controller 506 is an example of computing system 700.

Computing system 700 includes a logic machine 702 and a storage machine 704. Computing system 700 may optionally include a display subsystem 706, input subsystem 708, communication subsystem 710, and/or other components not shown in FIG. 7.

Logic machine 702 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 704 includes one or more physical devices configured to hold instructions executable by the logic machine to implement the methods and processes described herein. When such methods and processes are implemented, the state of storage machine 704 may be transformed—e.g., to hold different data.

Storage machine 704 may include removable and/or built-in devices. Storage machine 704 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 704 may include volatile, nonvolatile, dynamic, static, read/write, read-only, random-access, sequential-access, location-addressable, file-addressable, and/or content-addressable devices.

It will be appreciated that storage machine 704 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 702 and storage machine 704 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 706 may be used to present a visual representation of data held by storage machine 704. This visual representation may take the form of a graphical user interface (GUI). As the herein described methods and processes change the data held by the storage machine, and thus transform the state of the storage machine, the state of display subsystem 706 may likewise be transformed to visually represent changes in the underlying data. Display subsystem 706 may include one or more display devices utilizing virtually any type of technology. Such display devices may be combined with logic machine 702 and/or storage machine 704 in a shared enclosure, or such display devices may be peripheral display devices.

When included, input subsystem 708 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 710 may be configured to communicatively couple computing system 700 with one or more other computing devices. Communication subsystem 710 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 700 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or processes described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure comprises all novel and non-obvious combinations and sub-combinations of the various processes, systems and configurations, and other features, functions, acts, and/or properties disclosed herein, as well as any and all equivalents thereof.

1. A fabrication tool, comprising:
a chamber;
a pedestal electrode and a showerhead electrode arranged in the chamber;
one or more gas inlets into the chamber and associated flow control hardware;
a vacuum pump system configured to reduce a pressure within the chamber;
a radiofrequency (RF) power source configured to form an RF plasma between the pedestal electrode and the showerhead electrode; and
coupled operatively to the flow control hardware and to the RF power source, a controller comprising a processor and memory, the memory comprising instructions executable by the processor to:
operate the flow control hardware to introduce a hydrogen-containing reducing agent into the chamber,
operate the flow control hardware to introduce a hydrocarbon gas into the chamber, and
operate the RF power source to form a plasma between the pedestal electrode and the showerhead electrode to fully deposit a carbon plug in a recess of a workpiece positioned on a pedestal of the chamber in a single plasma deposition cycle with no intermediate carbon removal process.

2. The fabrication tool of claim 1, wherein the instructions are executable to operate the RF power source to provide RF power at one or more frequencies within a range of five megahertz and higher.

3. The fabrication tool of claim 2, wherein the instructions are executable to operate the RF power source to provide RF power that excludes frequencies below five megahertz.

4. The fabrication tool of claim 1, wherein the hydrocarbon gas comprises an alkyne.

5. The fabrication tool of claim 4, wherein the alkyne comprises acetylene.

6. The fabrication tool of claim 1, wherein the instructions are executable to operate the flow control hardware to introduce the hydrogen-containing reducing agent and the hydrocarbon gas into the chamber at a molar ratio of 20-35% hydrogen.

7. The fabrication tool of claim 1, wherein the instructions are further executable to further introduce one or more of argon or nitrogen into the chamber as a diluent gas.

8. The fabrication tool of claim 1, wherein the instructions are further executable to operate the flow control hardware to deposit the carbon plug at a processing gas pressure between 5 and 13 Torr.

9. The fabrication tool of claim 1, further comprising one or more heaters, and wherein the instructions are executable to operate the one or more heaters to maintain the pedestal electrode at a temperature within 275-660° C. during plug formation.

10. The fabrication tool of claim 1, wherein the instructions are executable to extinguish the plasma after the workpiece is exposed to the plasma for a duration within a range of 700 to 1800 seconds.

11. An integrated circuit fabrication method, comprising:
forming a carbon plug in a recess of a workpiece in a single plasma deposition cycle by exposing the workpiece to a carbon-depositing plasma in a plasma processing chamber, the plasma formed from a mixture of gases comprising
a hydrogen-containing reducing agent, and
a hydrocarbon gas.

12. The integrated circuit fabrication method of claim 11, wherein the carbon-depositing plasma comprises a radiofrequency (RF) plasma, the RF plasma comprising one or more frequencies within a range of five megahertz and higher.

13. The integrated circuit fabrication method of claim 11, wherein the hydrocarbon gas comprises an alkyne.

14. The integrated circuit fabrication method of claim 11, wherein the hydrogen-containing reducing agent and the hydrocarbon gas are introduced into the chamber at a molar ratio of 20-35% hydrogen.

15. The integrated circuit fabrication method of claim 11, wherein the mixture of gases further comprises one or more of argon or nitrogen as a diluent gas.

16. The integrated circuit fabrication method of claim 11, wherein the carbon plug is formed at a processing gas pressure between 5 and 13 Torr.

17. The integrated circuit fabrication method of claim 11, further comprising planarizing the workpiece after the single plasma deposition cycle, thereby removing carbon deposited outside of the recess.

18. The integrated circuit fabrication method of claim 11, wherein the recess comprises a channel of a memory stack structure.

19. A integrated circuit fabrication method of fabricating a memory stack structure, the method comprising:
supporting a workpiece on a pedestal of a deposition chamber, the deposition chamber comprising a pedestal electrode separated from a showerhead electrode by an interelectrode space, the workpiece comprising a recess in a first memory deck;
flowing a mixture of gases through the deposition chamber at reduced pressure, the mixture of gases comprising a hydrogen-containing reducing agent, and also comprising a hydrocarbon;
driving RF current through a discharge gap between the pedestal electrode and the showerhead electrode to form a carbon-depositing plasma and deposit a carbon plug in the recess in the first memory deck in a single deposition cycle;
planarizing the workpiece after forming the carbon plug in the recess in the first memory deck in the single deposition cycle; and
depositing layers of a second memory deck over the first memory deck and the carbon plug.

20. The integrated circuit fabrication method of claim 19, wherein the hydrocarbon comprises an alkyne.

21-22. (canceled)
